(19) United States
(12) Patent Application Publication
(10) Pub. No.: US 2026/0133230 A1
(43) Pub. Date: May 14, 2026

(54) ANISOTROPIC CONDUCTIVE SHEET, ELECTRICAL INSPECTION DEVICE, AND ELECTRICAL INSPECTION METHOD

(71) Applicant: MITSUI CHEMICALS, INC., Chuo-ku, Tokyo (JP)

(72) Inventors: Katsunori NISHIURA, Chiba-shi, Chiba (JP); Daisuke YAMADA, Hidaka-shi, Saitama (JP); Yuichi ITOU, Ichihara-shi, Chiba (JP); Masao HORI, Chiba-shi, Chiba (JP)

(73) Assignee: MITSUI CHEMICALS, INC., Chuo-ku, Tokyo (JP)

(21) Appl. No.: 18/706,261

(22) PCT Filed: Oct. 26, 2022
(86) PCT No.: PCT/JP2022/040008

§ 371 Date: Apr. 30, 2024

(30) Foreign Application Priority Data
Nov. 1, 2021 (JP) 2021-178804

(51) Int. Cl. G01R 27/08

(52) U.S. Cl. CPC G01R 27/08

(57) ABSTRACT

This anisotropic conductive sheet comprises: an insulation layer having an elastomer layer and a plurality of first heat-resistant resin layers disposed in a mutually separated manner on one side of the insulation layer; a plurality of through-holes disposed in the insulation layer; a plurality of conductive parts disposed on the respective inner wall surfaces of the plurality of through-holes; and a plurality of first conductive layers disposed on or above respective surfaces of the plurality of first heat-resistant resin layers and connected to the conductive parts. The plurality of through-holes are disposed at positions corresponding to the respective plurality of first heat-resistant resin layers. In a plan view of the insulation layer, the first conductive layers are located further to the inner side than the outer edge of the first heat-resistant resin layers.

### TECHNICAL FIELD

The present invention relates to an anisotropic conductive sheet, an electrical inspection device and an electrical inspection method.

### BACKGROUND ART

Semiconductor devices such as print wiring plates provided in electronic products are typically subjected to electrical inspection. Typically, electrical inspection is performed by electrically connecting a substrate of an electrical inspection device (including an electrode) and a terminal serving as an inspection object such as a semiconductor device, and reading a current obtained when a predetermined voltage is applied between the terminals of the inspection object. Further, an anisotropic conductive sheet is disposed between the substrate of the electrical inspection device and the inspection object in order to reliably electrically connect the electrode of the substrate of the electrical inspection device and the terminal of the inspection object.

The anisotropic conductive sheet is a sheet with a conductivity in the thickness direction and an insulation property in the surface direction, and is used as a probe (contact) in the electrical inspection. The anisotropic conductive sheet is used with a pushing load added for the purpose of reliably performing the electrical connection between the substrate of the electrical inspection device and the inspection object. Therefore, the anisotropic conductive sheet is required to be easily elastically deformed in the thickness direction.

As such anisotropic conductive sheets, various anisotropic conductive sheets have been examined (see PTL 1).

FIG. 1 is a schematic view illustrating anisotropic conductive sheet 10 disclosed in PTL 1. Anisotropic conductive sheet 10 includes insulating layer 11 including elastomer layer 11A and a plurality of first heat-resistant resin layers 11B disposed on one surface of it, a plurality of through holes 12 disposed at insulating layer 11, and a plurality of conductive layers 13 disposed corresponding to the plurality of through holes 12. The part between the plurality of conductive layers 13 is insulated by first groove 14, and the end portion of conductive layer 13 sandwiched by two first grooves 14 substantially overlaps the end portion of first heat-resistant resin layer 11B sandwiched by the two first grooves 14 (see FIG. 1).

### CITATION LIST

### Patent Literature

### PTL 1

WO2021/100824

### SUMMARY OF INVENTION

### Technical Problem

In some cases the width of first groove 14 is increased in the above-described anisotropic conductive sheet 10 for the purpose of preventing short circuit (see FIG. 2A). In that case, when terminal 321 of inspection object 320 is pushed to a position shifted from the center of conductive layer 13 (the broken line in FIG. 2A), the load easily concentrates at the end portion of first heat-resistant resin layer 11B, and first heat-resistant resin layer 11B and conductive layer 13 are easily inclined together (see FIG. 2B). As a result, the pushing load is easily diffused to the elastomer layer 11A, but is less transmitted to conductive layer 13, which may result in the increase in resistance value and the non-uniformity of the resistance value between the plurality of conductive layers 13.

Such defects may be eliminated by increasing the width of first heat-resistant resin layer 11B by reducing the width of first groove 14. However, when the width of first groove 14 is reduced, adjacent two conductive layers 13 easily make contact with each other at the time of pushing, which may result in short circuit.

In view of this, an object of the present invention is to provide an anisotropic conductive sheet, an electrical inspection device and an electrical inspection method that can maintain favorable conduction even when a pushing load is applied to a position shifted from a predetermined position while suppressing short circuit due to contact of a plurality of adjacent conductive layers.

### Solution to Problem

The above-described problems can be solved by the following configurations.

[1] An anisotropic conductive sheet including: an insulating layer including an elastomer layer, and a plurality of first heat-resistant resin layers disposed on or above one surface of the elastomer layer, the plurality of first heat-resistant resin layers being separated from one another: a plurality of through holes disposed in the insulating layer: a plurality of conductive parts disposed at respective inner wall surfaces of the plurality of through holes; and a plurality of first conductive layers disposed at respective surfaces of the plurality of first heat-resistant resin layers and connected with the plurality of conductive parts, in which the plurality of through holes is disposed at positions corresponding to the plurality of first heat-resistant resin layers, and in which in plan view of the insulating layer, each first conductive layer is located on an inner side of an outer edge of each first heat-resistant resin layer.

[2] The anisotropic conductive sheet according to claim [1], in which in plan view of the insulating layer, each first heat-resistant resin layer has a rectangular shape, and a ratio b/c of a length b of a short side of each first heat-resistant resin layer with respect to a distance c between centers of gravity of the plurality of first conductive layer is 0.65 or greater.

[3] The anisotropic conductive sheet according to claim [1] or [2], in which in plan view of the insulating layer, an area of each first conductive layer is 35 to 80% of an area of each first heat-resistant resin layer corresponding to each first conductive layer.

[4] The anisotropic conductive sheet according to any one of claims [1] to [3], in which a conductive filler is further provided inside the plurality of through holes.

[5] The anisotropic conductive sheet according to any one of claims [1] to [4], in which the insulating layer further includes a plurality of second heat-resistant resin layers disposed on or above another surface of the elastomer layer, the plurality of second heat-resistant resin layers being separated from one another other, in which the anisotropic conductive sheet further includes a plurality of second conductive layers disposed on or above surfaces of the plurality of second heat-resistant resin layers and connected to the plurality of conductive parts, in which the plurality of through holes is disposed at positions corresponding to the plurality of second heat-resistant resin layers, and in which in plan view of the insulating layer, each second conductive layer is located on an inner side of an outer edge of each second heat-resistant resin layer.

[6] The anisotropic conductive sheet according to any one of claims [1] to [5], in which the anisotropic conductive sheet is used for electrical inspection of an inspection object, and in which the inspection object is disposed on or above a surface on a first conductive layer side.

[7] An electrical inspection device including: an inspection substrate including a plurality of electrodes; and the anisotropic conductive sheet according to any one of claims [1] to [6] disposed on or above a surface of the inspection substrate on which the plurality of electrodes is disposed.

[8] An electrical inspection method including stacking an inspection substrate including a plurality of electrodes and an inspection object including a terminal through the anisotropic conductive sheet according to any one of claims [1] to [6] to electrically connect the plurality of electrodes of the inspection substrate and the terminal of the inspection object through the anisotropic conductive sheet.

### Advantageous Effects of Invention

According to the present invention, it is possible to provide an anisotropic conductive sheet, an electrical inspection device and an electrical inspection method that can maintain favorable conduction even when a pushing load is applied to a position shifted from a predetermined position while suppressing short circuit due to contact of a plurality of adjacent conductive layers.

### BRIEF DESCRIPTION OF DRAWINGS

FIG. 1 is a schematic partially enlarged sectional view illustrating an anisotropic conductive sheet disclosed in PTL 1:

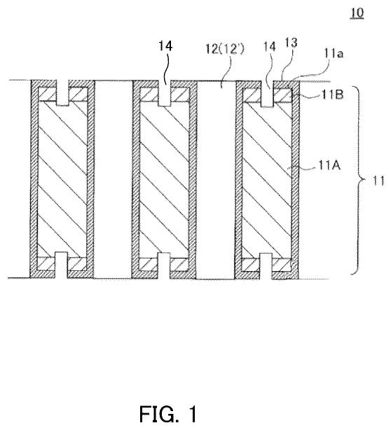

FIGS. 2A and 2B are schematic partially enlarged sectional views illustrating an operation of an anisotropic conductive sheet used for comparison:

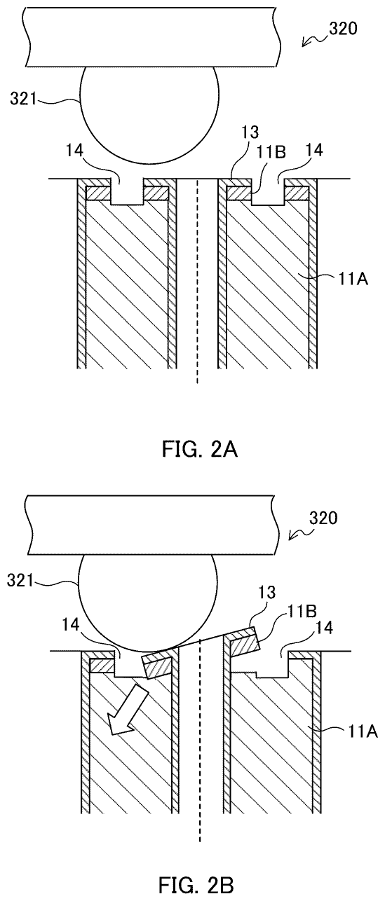

FIG. 3A is a schematic partially plan view illustrating an anisotropic conductive sheet according to the present embodiment, and FIG. 3B is a schematic partially enlarged sectional view illustrating the anisotropic conductive sheet of FIG. 3A taken along line 3B-3B:

FIG. 4 is a schematic partially enlarged sectional view illustrating the anisotropic conductive sheet of FIG. 3A taken along line 3B-3B:

FIGS. 5A and 5B are schematic partially enlarged sectional views illustrating an operation of the anisotropic conductive sheet according to the present embodiment:

FIG. 6A to 6D are schematic partially enlarged sectional views illustrating a manufacturing method for the anisotropic conductive sheet according to the present embodiment:

FIG. 7A to 7D are schematic partially enlarged sectional views illustrating a manufacturing method for the anisotropic conductive sheet according to the present embodiment:

FIG. 8A is a schematic sectional view illustrating an electrical inspection device according to the present embodiment, and FIG. 8B is a bottom view illustrating an exemplary inspection object:

FIGS. 9A and 9B are schematic enlarged plan views illustrating a first conductive layer of an anisotropic conductive sheet according to a modification;

FIGS. 10A and 10B are schematic partially enlarged sectional views illustrating an anisotropic conductive sheet according to a modification; and

FIG. 11 is a schematic view illustrating a measurement method for an electric resistance value.

### DESCRIPTION OF EMBODIMENTS

### 1. Anisotropic Conductive Sheet

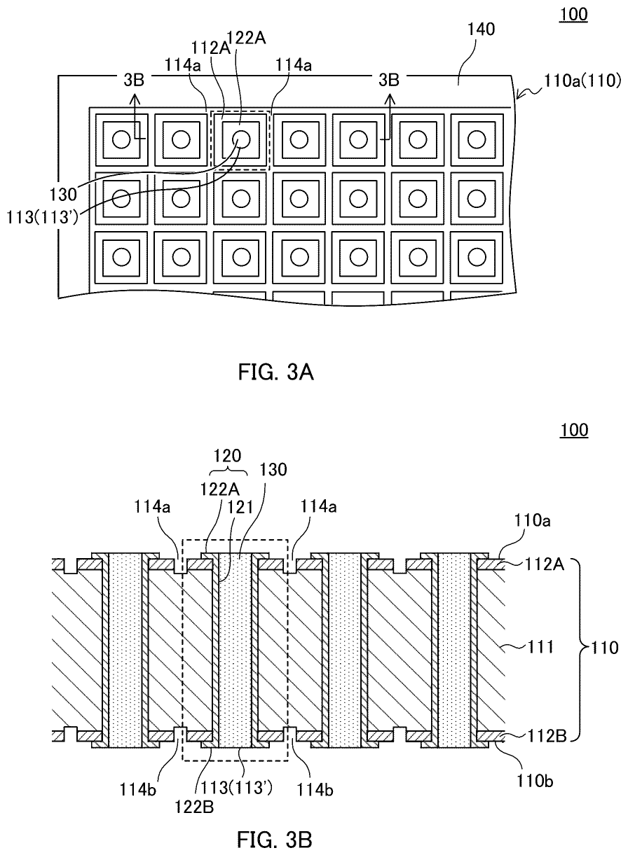

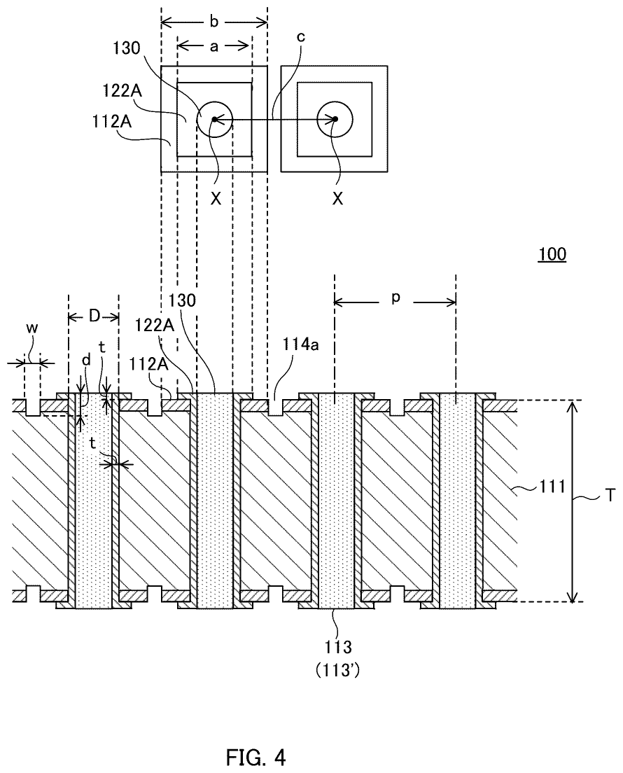

FIG. 3A is a schematic partially plan view illustrating anisotropic conductive sheet 100 according to the present embodiment, and FIG. 3B is a schematic partially enlarged sectional view illustrating anisotropic conductive sheet 100 of FIG. 3A taken along line 3B-3B. FIG. 4 is a schematic partially enlarged sectional view illustrating anisotropic conductive sheet 100 of FIG. 3A taken along line 3B-3B.

As illustrated in FIGS. 3A and 3B, anisotropic conductive sheet 100 includes insulating layer 110, a plurality of conductive layers 120, and a plurality of conductive fillers 130.

### 1-1. Insulating Layer 110

Insulating layer 110 includes elastomer layer 111, a plurality of first heat-resistant resin layers 112A separated from one another other and disposed on or above one surface of elastomer layer 111, and a plurality of second heat-resistant resin layers 112B separated from one another other and disposed on or above the other surface of elastomer layer 111. In addition, insulating layer 110 further includes a plurality of through holes 113 extending between first surface 110a and second surface 110b. Note that preferably, in the present embodiment, an inspection object is disposed on first surface 110a of insulating layer 110.

### Elastomer Layer 111

Elastomer layer 111 has an elasticity with which it elastically deforms when a pressure is applied to it in the thickness direction. Specifically, preferably, elastomer layer 111 is an elastic layer, and contains a cross-linked elastomer composition.

The elastomer contained in the elastomer composition is not limited, but is preferably an elastomer such as silicone rubber, urethane rubber (urethane polymer), acrylic rubber (acrylic polymer), ethylene-propylene-diene copolymer (EPDM), chloroprene rubber, styrene-butadiene copolymer, acrylic nitrile-butadiene copolymer, poly butadiene rubber, natural rubber, polyester thermoplastic elastomer, olefin thermoplastic elastomer, and fluorinated rubber, for example. Among them, silicone rubber is preferable. Silicone rubber may be addition, condensation or radical type.

The elastomer composition may further contain crosslinking agent as necessary. The crosslinking agent may be selected as necessary in accordance with the type of the elastomer. Examples of the crosslinking agent of the silicone rubber include addition reaction catalysts such as metals, metal compounds and metal complexes with catalytic activity for hydrosilylation reactions (such as platinum, platinum compounds and their complexes); and organic peroxides such as benzoyl peroxide, bis-2,4-dichlorobenzoyl peroxide, dicumyl peroxide and di-t-butyl peroxide. Examples of the crosslinking agent of the acrylic rubber (acrylic polymer) include epoxy compounds, melamine compounds and isocyanate compounds.

Examples of the cross-linked composition of the silicone rubber include addition cross-linked silicone rubber compositions containing organopolysiloxanes with hydrosilyl groups (SiH groups) and organopolysiloxanes with vinyl groups and addition reaction catalysts: addition cross-linked silicone rubber compositions containing organopolysiloxanes with vinyl groups and addition reaction catalysts; and cross-linked silicone rubber compositions containing organopolysiloxanes with SiCH3 groups and organic peroxide curing agents.

The elastomer composition may further contain other components such as silane coupling agents, fillers and the like, as necessary.

The glass transition temperature of the cross-linked elastomer composition is not limited, but is preferably −30° C. or below, more preferably −40° C. or below in view of preventing scratches on the terminals of the inspection object. The glass transition temperature may be measured in accordance with JIS K 7095:2012.

Preferably, the storage modulus of the cross-linked elastomer composition at 25° C. is 1.0×10⁷ Pa or smaller, more preferably 1.0×10⁵ to 9.0×10⁶ Pa. The storage modulus of the cross-linked elastomer composition may be measured in accordance with JISK7244-1: 1998/ISO6721-1:1994.

The glass transition temperature and the storage modulus of the cross-linked elastomer composition may be adjusted by the compositions of the elastomer composition.

### First Heat-Resistant Resin Layer 112A

The plurality of first heat-resistant resin layers 112A separated from one another other and disposed on or above one surface of elastomer layer 111. In the present embodiment, the plurality of first heat-resistant resin layers 112A is defined by first groove 114a. First heat-resistant resin layer 112A has a heat resisting property higher than that of elastomer layer 111, and thus can suppress variation of the distance between centers of gravity of a plurality of first conductive layers 122A due to the heat even when heated during the electrical inspection.

In plan view of insulating layer 110, the shape of first heat-resistant resin layer 112A is not limited, but may be any of rectangular shapes, triangular shapes, polygonal shapes, and circular shapes. In the present embodiment, the shape of the plurality of first heat-resistant resin layers 112A is a rectangular shape (see FIG. 3A). In addition, the shapes and sizes of the plurality of first heat-resistant resin layers 112A are the same (see FIG. 3A).

Preferably, in plan view of insulating layer 110, ratio b/c of the length of short side b of first heat-resistant resin layer 112A with respect to distance c between centers of gravity of the plurality of first conductive layers 122A is 0.65 or greater (see FIG. 4). In the case where the b/c is 0.65 or greater, even when the pushing load is applied to a position shifted from the center of gravity of first conductive layer 122A, first heat-resistant resin layer 112A is not easily distorted by the load, and thus the load is not easily diffused to elastomer layer 111. In addition, since the load is not easily concentrated at the end portion of first heat-resistant resin layer 112A, first heat-resistant resin layer 112A is not easily inclined together with first conductive layer 122A. On the other hand, preferably, the b/c is 0.90 or smaller in view of preventing the plurality of first heat-resistant resin layers 112A from making contact with each other, and preventing the surrounding first heat-resistant resin layer 112A from being pushed together when the pushing load is applied. From the same view point, it is more preferable that the b/c be 0.70 to 0.88. Note that the short side of the square may be any side of the square. In addition, the center of gravity of first conductive layer 122A (in FIG. 4, center of gravity X) means the center of gravity of a shape assumed to have no through hole 113 in plan view of first conductive layer 122A.

Preferably, distance c between centers of gravity of the plurality of first conductive layers 122A is distance c between centers of gravity in the short side direction of first heat-resistant resin layer 112A.

Preferably, the glass transition temperature of the heat-resistant resin composition making up first heat-resistant resin layer 112A is higher than the glass transition temperature of the cross-linked elastomer composition making up elastomer layer 111. More specifically, preferably, the glass transition temperature of the heat-resistant resin composition is 150° C. or above, more preferably 150 to 500° C. because the electrical inspection is performed at approximately-40 to 150° C. The glass transition temperature may be measured by the above-described method.

Preferably, the linear expansion coefficient of the heat-resistant resin composition is lower than the linear expansion coefficient of the cross-linked elastomer composition. More specifically, preferably, the linear expansion coefficient of the heat-resistant resin composition described above is 60 ppm/K or smaller, more preferably 50 ppm/K or smaller. Preferably, the storage modulus of the heat-resistant resin composition at 25° C. is higher than the storage modulus of the cross-linked elastomer composition at 25° C.

Preferably, the composition of the heat-resistant resin composition is not limited as long as the glass transition temperature, the linear expansion coefficient or the storage modulus satisfies the above-described range. The resin contained in the heat-resistant resin composition is a heat-resistant resin the glass transition temperature of which satisfies the above-described range, and examples of such a resin include engineering plastic such as polyamide, polycarbonate, polyarylate, polysulfone, polyether sulfone, polyphenylene sulfide, polyetheretherketone, polyimide, and polyetherimide, acrylic resin, urethane resin, epoxy resin, and olefin resin. The heat-resistant resin composition may further contain other components such as filler as necessary.

The thickness of first heat-resistant resin layer 112A is not limited, but is preferably smaller than the thickness of elastomer layer 111 in view of suppressing impairment of the elasticity of insulating layer 110 (see FIG. 4). More specifically, preferably, the ratio (T2/T1) of the thickness (T2) of first heat-resistant resin layer 112A and the thickness (T1) of elastomer layer 111 is 1/99 to 30/70, more preferably 2/98 to 10/90. When first heat-resistant resin layer 112A has a certain thickness ratio or greater, an appropriate hardness (stiffness) can be provided to insulating layer 110 without impairing the elasticity of insulating layer 110. This can not only increase the handleability, but also suppress the variation of the center-to-center distance of the plurality of through holes 113 due to heat.

The thickness of insulating layer 110 is not limited as long as the insulation property in the non-conduction portion can be ensured, and may be 40 to 700 μm, preferably 100 to 400 μm, for example.

As described above, first groove 114a is disposed between the plurality of first heat-resistant resin layers 112A. Specifically, first groove 114a is a valley disposed at first surface 110a.

The cross-sectional shape of first groove 114a in the direction orthogonal to the extending direction is not limited, and may be a rectangular shape, a semicircular shape, a U shape, or a V shape. In the present embodiment, first groove 114a has a rectangular cross-sectional shape.

Preferably, width w and depth d of first groove 114a are set in a range with which first heat-resistant resin layer 112A on one side and first heat-resistant resin layer 112A on the other side do not make contact with each other through first groove 114a when a pushing load is applied (see FIG. 4). The reason for this is to easily transmit the pushing load to first heat-resistant resin layer 112A.

Width w of first groove 114a may be set such that the b/c is within the above-described range. Width w of first groove 114a is the maximum width in the direction orthogonal to the extending direction of first groove 114a in first surface 110a (see FIG. 4).

Preferably, depth d of first groove 114a is the same as or greater than the thickness of first heat-resistant resin layer 112A. Specifically, the deepest part of first groove 114a may be located at or inside the surface of elastomer layer 111. Depth d of first groove 114a is the depth from the surface of first conductive layer 122A to the deepest part in the thickness direction of insulating layer 11 (see FIG. 4). Note that width w and depth d of first groove 114a may be the same or different from each other.

In this manner, with the plurality of first heat-resistant resin layers 112A divided by first groove 114a, the surrounding conductive layer 120 can be prevented from being pushed together when pushed with inspection object 320 put on it, and thus the influence on the surrounding conductive layer 120 can be reduced.

### Second Heat-Resistant Resin Layer 112B

The plurality of second heat-resistant resin layers 112B is separated from one another other and disposed on or above the other surface of elastomer layer 111. In the present embodiment, second heat-resistant resin layer 112B has the same configuration as that of the above-described first heat-resistant resin layer 112A or a configuration similar to it, and therefore the description thereof is omitted. That is, the shape, material and physical property and the like of second heat-resistant resin layer 112B may be the same as or similar to the shape, material and physical property and the like of the above-described first heat-resistant resin layer 112A. In addition, second groove 114b disposed between the plurality of second heat-resistant resin layers 112B in second surface 110b may be the same or similar to first groove 114a disposed between the plurality of first heat-resistant resin layers 112A in first surface 110a.

Note that the composition of the heat-resistant resin composition making up first heat-resistant resin layer 112A and the composition of the heat-resistant resin composition making up second heat-resistant resin layer 112B may be different from each other. In addition, the thickness of first heat-resistant resin layer 112A and the thickness of second heat-resistant resin layer 112B may be different from each other; however, it is preferable that they are the same in view of suppressing the warp of anisotropic conductive sheet 100, and the ratio of the thickness of second heat-resistant resin layer 112B with respect to the thickness of first heat-resistant resin layer 112A may be 0.8 to 1.2, for example.

### Through Hole 113

The plurality of through holes 113 is holes extending between first surface 110a and second surface 110b of insulating layer 110, and is disposed at positions corresponding to the plurality of first heat-resistant resin layers 112A and second heat-resistant resin layers 112B (see FIG. 3B).

The axis direction of through hole 113 may be approximately parallel or tilted with respect to the thickness direction of insulating layer 110. The approximately parallel state is a state where the angle with respect to the thickness direction of insulating layer 110 is 10° or smaller. The inclined state is a state where the angle with respect to the thickness direction of insulating layer 110 is greater than 10° and equal to or smaller than 50°, preferably 20 to 45°. In the present embodiment, the axis direction of through hole 113 is approximately parallel to the thickness direction of insulating layer 110 (see FIG. 3B). Note that the axis direction is a direction of a line connecting the centers of gravity (or centers) of the opening on the first surface 110a side and the opening of through hole 113 on the second surface 110b side of through hole 113.

The shape of the opening of through hole 113 in first surface 110a is not limited, and may be any of circular shapes, quadrangular shapes, and other polygonal shapes, for example. In the present embodiment, the shape of the opening of through hole 113 in first surface 110a is a circular shape (see FIGS. 3A and 3B). In addition, the shape of the opening of through hole 113 on the first surface 110a side and the shape of the opening on the second surface 110b side may be the same or different from each other, but is preferably the same in view of the stability of connection to electronic devices to be measured.

Circle equivalent diameter D of the opening of through hole 12 on the first surface 110a side is not limited, but is preferably 1 to 330 μm, more preferably 2 to 200 μm, still more preferably 10 to 100 μm, for example (see FIG. 4). Circle equivalent diameter D of the opening of through hole 113 on the first surface 110a side is a circle equivalent diameter (the diameter of a true circle corresponding to the area of the opening) of the opening of through hole 113 as viewed along the axis direction of through hole 113 from the first surface 110a side.

Circle equivalent diameter D of the opening of through hole 113 on the first surface 110a side and circle equivalent diameter D of the opening of through hole 113 on the second surface 110b side may be the same or different from each other.

Center-to-center distance (pitch) p of the openings of the plurality of through holes 113 on the first surface 110a side is not limited, and may be appropriately set in accordance with the pitch of the terminal of the inspection object (see FIG. 4). Since the pitch of the terminal of an HBM (High Bandwidth Memory) as an inspection object is 55 μm, and the pitch of the terminal of POP (PackageonPackage) is 400 to 650 μm, center-to-center distance p of the openings of the plurality of through holes 113 may be 5 to 650 μm, for example. Among them, center-to-center distance p of the openings of the plurality of through holes 113 on the first surface 110a side is preferably 5 to 55 μm in view of eliminating the necessity of the alignment (in view of achieving alignment free) of the terminal of the inspection object. Center-to-center distance p of the openings of the plurality of through holes 113 on the first surface 110a side is the smallest value of the center-to-center distances of the openings of the plurality of through holes 113 on first surface 110a side. The center of the opening of through hole 113 is the center of gravity of the opening. In addition, center-to-center distance p of the openings of the plurality of through holes 113 may be the same or different in the axis direction.

Ratio T/D of the length in the axis direction of through hole 113 (thickness T of insulating layer 11) and circle equivalent diameter D of the opening of through hole 113 on the first surface 110a side is not limited, but is preferably 3 to 40 (see FIG. 4).

### 1-2. Conductive Layer 120

Conductive layer 120 is disposed correspondingly for one or more through holes 113. Conductive layer 120 includes conductive part 121, first conductive layer 122A, and second conductive layer 122B.

Conductive part 121 is disposed at the inner wall surface of through hole 113.

First conductive layer 122A is disposed on or above the surface (on first surface 110a side) of first heat-resistant resin layer 112A, and is connected to conductive part 121. Second conductive layer 122B is disposed on or above the surface (on second surface 110b side) of second heat-resistant resin layer 112B, and is connected to conductive part 121.

In plan view of insulating layer 110, the shapes of first conductive layer 122A and second conductive layer 122B are not limited, and may be any of rectangular shapes, triangular shapes, polygonal shapes, and circular shapes. In the present embodiment, the shapes of first conductive layer 122A and second conductive layer 122B are rectangular shapes (see FIG. 3A). In addition, the shapes and sizes of the plurality of first conductive layers 122A are the same, and the shapes and sizes of the plurality of second conductive layers 122B are the same. In addition, the shape of first conductive layer 122A and the shape of first heat-resistant resin layer 112A may be the same (similar) or different, and the shape of second conductive layer 122B and the shape of second heat-resistant resin layer 112B may be the same (similar) or different.

Distance c between centers of gravity of the plurality of first conductive layers 122A on the first surface 110a side is not limited, but is preferably 5 to 650 μm, more preferably 10 to 300 μm, for example. In addition, in the present embodiment, distance c between centers of gravity of the plurality of first conductive layers 122A on the first surface 110a side is the same as the distance between centers of gravity of the plurality of first heat-resistant resin layers 112A on the first surface 110a side. The center of gravity of the plurality of first heat-resistant resin layers 112A means the center of gravity of the shape assumed to have no through hole 113 in plan view of first heat-resistant resin layer 112A. The distance between centers of gravity of the plurality of second conductive layers 122B on the second surface 110b side may also be the same or similar to that of first conductive layer 122A.

Further, in plan view of insulating layer 110, first conductive layer 122A is located on the inner side than the outer edge of first heat-resistant resin layer 112A, and second conductive layer 122B is located on the inner side than the outer edge of second heat-resistant resin layer 112B (see FIGS. 3A and 3B). Specifically, in plan view of insulating layer 110, the periphery of first conductive layer 122A is surrounded by first heat-resistant resin layer 112A. In this manner, the plurality of adjacent first conductive layers 122A less make contact with each other even when the width of first groove 114a is reduced (even when b/c is increased), and thus the short circuit can be suppressed.

In plan view of insulating layer 110, the area of first conductive layer 122A is smaller than the area of corresponding first heat-resistant resin layer 112A, and the area of second conductive layer 122B is smaller than the area of corresponding second heat-resistant resin layer 112B. More specifically, preferably, the area of first conductive layer 122A is 35 to 80% of the area of corresponding first heat-resistant resin layer 112A. When the area of first conductive layer 122A is 80% or less of the area of first heat-resistant resin layer 112A, the short circuit due to the contact between first conductive layers 122A is easily suppressed. When the area of first conductive layer 122A is 35% or greater of the area of first heat-resistant resin layer 112A, the contact area of first conductive layer 122A and the terminal of the inspection object during the electrical inspection is not excessively reduced, and the increase in resistance value can be easily suppressed. In addition, in view of placing importance on the reduction in resistance value and the like, the area of first conductive layer 122A may be set to 50 to 75% of the area of first heat-resistant resin layer 112A. Note that the area of first conductive layer 122A means the area of the shape of first conductive layer 122A assumed to have no through hole 113, and the area of first heat-resistant resin layer 112A means the area of the shape of first heat-resistant resin layer 112A assumed to have no through hole 113.

For example, length a of the short side of first conductive layer 122A is smaller than length b of the short side of first heat-resistant resin layer 112A. More specifically, ratio a/b of length a of the short side of first conductive layer 122A to length b of the short side of first heat-resistant resin layer 112A is preferably 0.5 to 0.9. When the a/b is 0.9 or less, the contact between first conductive layers 122A can be suppressed even when the width of first groove 114a is small, i.e., even when b/c is large, and thus the short circuit can be easily suppressed. When the a/b is 0.5 or greater, the increase in resistance value can be easily suppressed because the area of first conductive layer 122A is not excessively small. From the same view point, the a/b is preferably 0.6 to 0.88.

The ratio of the areas and the ratio of the short side lengths of second conductive layer 122B and second heat-resistant resin layer 112B may be the same or similar to those of the above-described case of first conductive layer 122A and first heat-resistant resin layer 112A.

The ratios of the areas and the short side lengths can be obtained from images analyzed with various microscopes such as microscopes and image dimension measuring devices. For example, they may be obtained as average values of the ratios of the areas and the ratios of the short side lengths of three to five first conductive layers 122A and their corresponding first heat-resistant resin layers 112A.

The volume resistivity of the material of conductive layer 120 is not limited as long as sufficient conduction can be obtained, and is preferably 1.0×10⁻⁴ Ω·m or smaller, more preferably 1.0×10⁻⁵ to 1.0×10⁻⁹ Ω·m. The volume resistivity can be measured by the method described in ASTM D 991.

The volume resistivity of the material of conductive layer 120 needs only to satisfy the above-described range. Examples of the material of conductive layer 120 include metal materials such as copper, gold, platinum, silver, nickel, tin, iron or their alloys, and carbon materials such as carbon black. Among them, it is preferable that conductive layer 120 contain as its main constituent one or more selected from the group consisting of gold, silver and copper in view of high conductivity and flexibility. The state containing as the main constituent is a state of 70 wt % or more, preferably 80 wt % or more with respect to conductive layer 120, for example.

The materials of conductive part 121, first conductive layer 122A and second conductive layer 122B may be the same or different from each other, but are preferably the same in view of the ease of manufacture and the stability of conduction.

It suffices that the thickness of conductive layer 120 is set to a range in which sufficient conduction is obtained and that through hole 113 is not closed, and may be 0.1 to 5 μm, for example. In conductive layer 120, the thickness of conductive part 121 is the thickness in the direction orthogonal to the thickness direction of insulating layer 110, and the thicknesses of first conductive layer 122A and second conductive layer 122B are the thickness in the direction parallel to the thickness direction of insulating layer 110 (see reference numeral t of FIG. 4).

### 1-3. Conductive Filler 130

Conductive filler 130 is provided in hollow 113′ of through hole 113 surrounded by conductive part 121, and can suppress the peeling of conductive part 121 while maintaining the conductivity.

Conductive filler 130 includes a cross-linked conductive elastomer composition containing conductive particles and elastomers.

The material of conductive particles is not limited, but particles containing one or more selected from the group consisting of gold, silver, and copper are preferable in view of excellent conductivity and flexibility.

The type of the elastomer is not limited, and may be the same as the elastomer used for the elastomer composition making up insulating layer 110. The type of the elastomer used for the conductive elastomer composition may be the same as or different from the type of the elastomer used for the elastomer composition making up the insulating layer 110, but silicone rubber is preferable in view of flexibility and the like.

The content of elastomer is preferably 5 to 50 wt % with respect to the total amount of the conductive particles and elastomer. When the content of elastomer is 5 wt % or greater, the adhesion to the inner wall surface of through hole 113 of conductive part 121 is easily increased, and the cross-linked conductive elastomer composition has sufficient flexibility, and thus, the cracking and peeling of conductive part 121 can be easily suppressed.

The conductive elastomer composition may contain other components such as crosslinking agents as necessary. The type of crosslinking agent is not limited, and may be the same as the crosslinking agent used for the elastomer composition making up insulating layer 110.

The storage of the cross-linked conductive elastomer composition modulus at 25° C. is not limited, but normally, it is likely to be higher than the storage modulus of the cross-linked elastomer composition making up insulating layer 110 at 25° C. However, it is preferably moderately low in view of suppressing the defects due to the pressure concentrated at conductive filler 130 during the pushing. More specifically, the storage modulus of the cross-linked conductive elastomer composition at 25° C. is preferably 1 to 300 MPa, more preferably 2 to 200 MPa. The storage modulus can be measured by the compression deformation mode by the same method as the above-described method.

The cross-linked conductive elastomer composition preferably has a predetermined conductivity or greater. More specifically, the volume resistivity of the cross-linked conductive elastomer composition is preferably 10⁻² Ω·m or less, more preferably 1×10⁻⁸ to 1×10⁻² Ω·m. The volume resistivity can be measured by the above-described method.

### 1-4. Operations

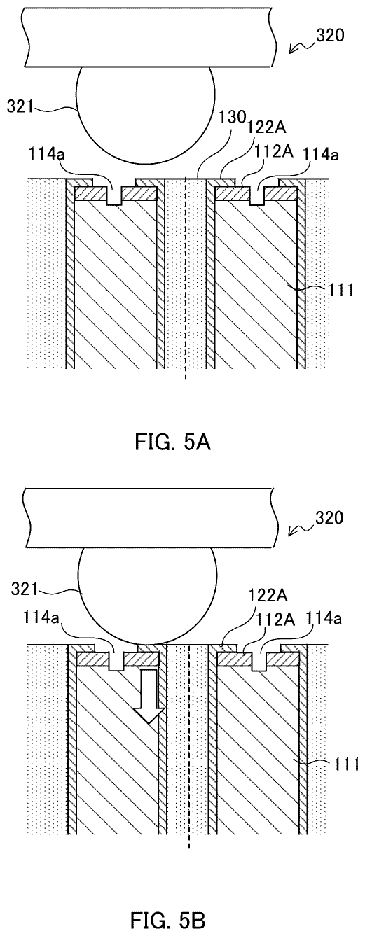

An operation of anisotropic conductive sheet 100 according to the present embodiment is described. FIGS. 5A and 5B are schematic partially enlarged sectional views illustrating an operation of anisotropic conductive sheet 100 according to the present embodiment.

In anisotropic conductive sheet 100 of the present embodiment, first conductive layer 122A is located on the inner side than the outer edge of first heat-resistant resin layer 112A in plan view of insulating layer 110 (see FIG. 5A). Specifically, first conductive layer 122A is supported by first heat-resistant resin layer 112A larger than first conductive layer 122A. Thus, even when a pushing load is applied to a position shifted from the center of gravity of first conductive layer 122A (the broken line in FIGS. 5A and 5B), the load is dispersed at first heat-resistant resin layer 112A and is not easily diffused to elastomer layer 111. That is, the situation where first heat-resistant resin layer 112A and first conductive layer 122A are inclined together can be suppressed. In this manner, the pushing load can be easily transmitted to first conductive layer 122A, conductive part 121, and conductive filler 130 (see FIG. 5B).

In addition, since first conductive layer 122A is located on the inner side than the outer edge of first heat-resistant resin layer 112A, the adjacent first conductive layers 122A less make contact with each other during the pushing even when the width of first groove 114a is reduced. In this manner, the short circuit during the pushing can be suppressed.

Thus, even when a pushing load is applied to a position shifted from the center of gravity, the increase in resistance value and the non-uniformity of the resistance value can be suppressed while suppressing the short circuit due to the contact of the plurality of adjacent first conductive layers 122A.

### 2. Manufacturing Method for Anisotropic Conductive Sheet

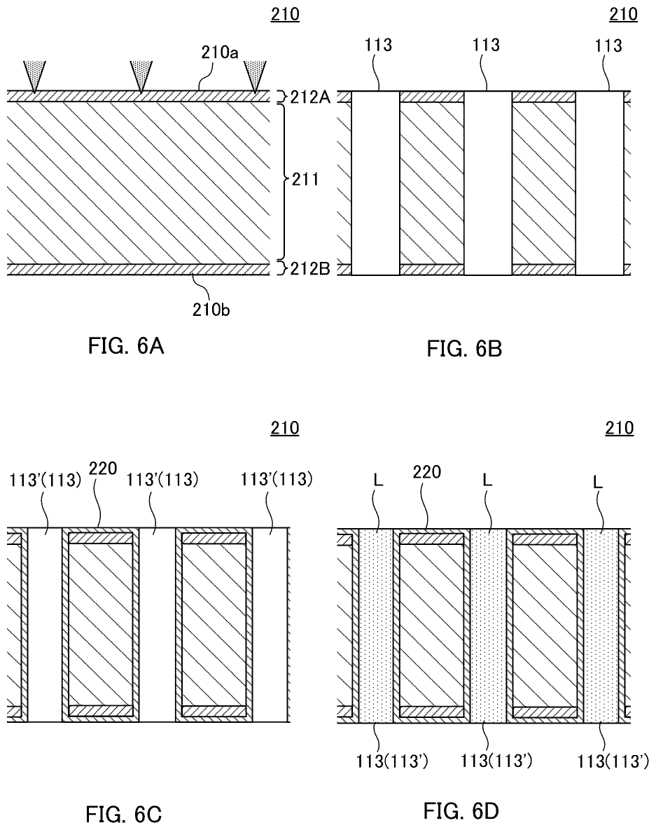

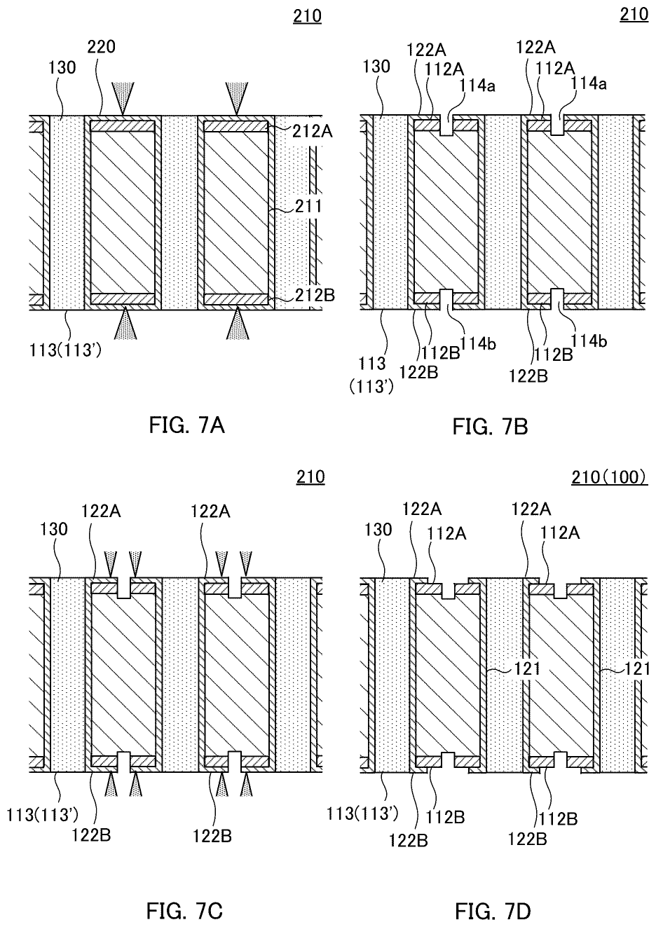

FIGS. 6A to 6D and 7A to 7D are schematic partially enlarged sectional views illustrating a manufacturing method for an anisotropic conductive sheet according to the present embodiment.

For example, anisotropic conductive sheet 100 according to the present embodiment can be manufactured through step 1) of preparing laminate sheet 210 including elastomer layer 211 and heat-resistant resin layer 212A and 212B, and the plurality of through holes 113 (see FIGS. 6A and 6B), step 2) of forming one continuous conductive layer 220 at a surface of the insulating sheet 210 (see FIG. 6C), step 3) of providing conductive elastomer composition L inside the plurality of through holes 113 (see FIG. 6D), step 4) of forming first groove 114a and second groove 114b in first surface 210a and second surface 210b of insulating sheet 210, dividing heat-resistant resin layer 212A and 212B into the plurality of first heat-resistant resin layers 112A and the plurality of second heat-resistant resin layers 112B, respectively, dividing first surface 110a side of conductive layer 220 into the plurality of first conductive layers 122A, and dividing second surface 110b side into the plurality of second conductive layers 122B (see FIGS. 7A and 7B), and step 5) of removing the outer periphery part of first conductive layer 122A and second conductive layer 122B (see FIGS. 7C and 7D).

### Step 1

First, laminate sheet 210 including elastomer layer 211 and heat-resistant resin layer 212A and 212B, and the plurality of through holes 113 is prepared (FIGS. 6A and 6B).

For example, laminate sheet 210 including elastomer layer 211 and two heat-resistant resin layers 212A and 212B is prepared (see FIG. 6A). Elastomer layer 211 contains the above-described cross-linked elastomer composition, and heat-resistant resin layer 212A and 212B contain the above-described heat-resistant resin composition.

Next, the plurality of through holes 113 is formed in laminate sheet 210 (see FIG. 6B).

Through hole 113 may be formed by any method. For example, it may be formed by a method of mechanically forming holes (e.g., pressing and punching), a laser processing method and the like. Among them, a laser processing method is preferable to form through hole 12 in view of the capability of forming through hole 12 with a minute and highly precise shape.

For the laser, excimer laser, carbon dioxide laser, YAG laser and the like that can precisely form holes in resin may be used. Among them, excimer laser is preferable. The pulse width of the laser is not limited, and may be any of micro second laser, nanosecond laser, picosecond laser, and femtosecond laser. In addition, the wavelength of the laser is not limited.

### Step 2

Next, one continuous conductive layer 220 is formed at the entire surface of laminate sheet 210 in which a plurality of through holes 213 is formed (see FIG. 6C). More specifically, in insulating sheet 210, conductive layer 220 is continuously formed at the inner wall surfaces of the plurality of through holes 213, and first surface 210a and second surface 210b around the openings thereof. In this manner, a plurality of hollows 113′ corresponding to through holes 113 and surrounded by conductive layer 220 is formed.

Conductive layer 220 may be formed by any method, but it is preferable to use a plating method (e.g., an electroless plating method and a lectrolytic plating method) in view of forming conductive layer 220 with a small and uniform thickness without closing through hole 113.

### Step 3

Next, conductive elastomer composition L is provided inside the plurality of hollows 113′ surrounded by conductive layer 220 (see FIG. 6D).

Conductive elastomer composition L may be provided by vacuuming the inside of hollow 12′ from second surface 210b side in the state where conductive elastomer composition L is applied on first surface 210a, for example.

Then, conductive elastomer composition L provided is crosslinked. In the case where conductive elastomer composition L contains solvent, it is preferable to be dried further.

### Step 4

Next, first groove 114a and second groove 114b are formed at first surface 210a and second surface 210b, respectively of laminate sheet 210 (see FIGS. 7A and 7B). In this manner, first surface 210a side of conductive layer 220 is divided into the plurality of first conductive layers 122A, and second surface 210b side of conductive layer 220 is divided into the plurality of second conductive layers 122B. In addition, heat-resistant resin layer 212A is divided into the plurality of first heat-resistant resin layers 112A, and heat-resistant resin layer 212B is divided into the plurality of second heat-resistant resin layers 112B (see FIGS. 7A and 7B).

First groove 114a and second groove 114b may be formed by a laser processing method, for example. In the present embodiment, the plurality of first grooves 114a and the plurality of second grooves 114b may be formed in a grid form.

### Step 5

Then, the outer periphery parts of first conductive layer 122A and second conductive layer 122B are further removed (see FIGS. 7C and 7D).

More specifically, in plan view of insulating layer 110, first conductive layer 122A is removed such that first conductive layer 122A is located on the inner side than the outer edge of first heat-resistant resin layer 112A, and second conductive layer 122B is removed such that second conductive layer 122B is located on the inner side than the outer edge of second heat-resistant resin layer 112B. The outer periphery part can be removed by laser processing, for example.

The order of the above-described steps of 4) and 5) may be interchanged. Specifically, in first surface 210a and second surface 210b, after forming grooves in conductive layer 220 so as to perform division into the plurality of first conductive layers 122A and second conductive layers 122B, grooves may be formed in heat-resistant resin layer 212A and 212B so as to perform division into the plurality of first heat-resistant resin layers 112A and second heat-resistant resin layers 112B. In that case, it is preferable that the width of the groove formed later be smaller than the width of the groove formed earlier.

The manufacturing method for anisotropic conductive sheet 100 according to the present embodiment may further include other steps than the above-described steps as necessary. For example, step 6) of pre-treatment for increasing the ease of formation of conductive layer 220 may be performed between the steps 2) and 3).

### Step 6

It is preferable to perform desmear treatment (pre-treatment) for increasing the ease of formation of conductive layer 220 for laminate sheet 210 in which the plurality of through holes 113 is formed. The desmear treatment includes a wet treatment and dry treatment, and any of them may be used.

As the wet desmear treatment, publicly known wet treatments such as an alkali treatment, a sulfuric acid method, a chromic acid method, and a permanganate method may be employed.

Examples of the dry desmear treatment include a plasma treatment. For example, in the case where insulating sheet 21 is composed of a silicone cross-linked elastomer composition, not only ashing/etching, but also formation of a silica film through oxidation of the surface of the silicone can be achieved by performing plasma treatment on insulating sheet 21. Forming the silica film can increase the ease of infiltration of plating solution into through hole 12, and increase the adhesion between conductive layer 22 and the inner wall surface of through hole 12.

The oxygen plasma treatment can be performed with a plasma asher, a high-frequency plasma etching device, and/or a microwave plasma etching device, for example.

### 3. Electrical Inspection Device and Electrical Inspection Method

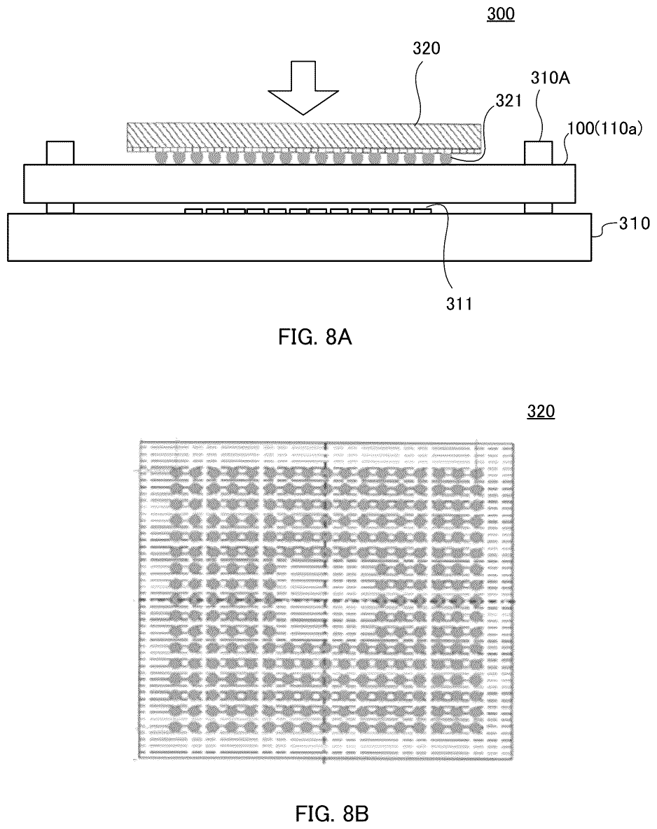

FIG. 8A is a schematic sectional view illustrating electrical inspection device 300 according to the present embodiment, and FIG. 8B is a bottom view illustrating an exemplary inspection object.

Electrical inspection device 300 is a device for inspecting the electrical characteristics (such as conduction) between terminals 321 (measurement points) of inspection object 320. Note that the drawing also illustrates inspection object 320 for the purpose of describing the electrical inspection method.

As illustrated in FIG. 8A, electrical inspection device 300 includes inspection substrate 310 with a plurality of electrodes, and anisotropic conductive sheet 100.

Inspection substrate 310 includes, at the surface that faces inspection object 320, a plurality of electrodes 311 that faces measurement points of inspection object 320.

Anisotropic conductive sheet 100 is disposed on or above the surface of inspection substrate 310 on which electrode 311 is disposed, such that the electrode 311 and second conductive layer 122B on second surface 110b side in anisotropic conductive sheet 100 are in contact with each other.

Further, in electrical inspection device 300, anisotropic conductive sheet 100 can be positioned and installed on inspection substrate 310 with guide pin 310A of inspection substrate 310 inserted in the positioning hole (not illustrated in the drawing) of anisotropic conductive sheet 100. Further, inspection object 320 can be disposed on or above anisotropic conductive sheet 10 such that they are pressed and fixed by using a pressing jig.

Examples of inspection object 320 may be, but not limited to, various semiconductor devices (semiconductor packages) such as HBM and POP, and electronic components, and printed boards. In the case where inspection object 320 is a semiconductor package, the measurement point may be a bump (terminal). In addition, in the case where inspection object 320 is a printed board, the measurement point may be a measuring land or a component mounting land provided in a conductive pattern. Examples of inspection object 320 include a chip in which a total of 264 solder ball electrodes (material: lead-free solder) with a diameter of 0.2 mm and a height of 0.17 mm are arranged at a 0.3 mm pitch (see FIG. 8B).

An electrical inspection method using electrical inspection device 300 of FIG. 8A is described below.

As illustrated in FIG. 8A, the electrical inspection method according to the present embodiment includes a step of stacking inspection substrate 310 provided with electrode 311 and inspection object 320 through anisotropic conductive sheet 100, and electrically connecting electrode 311 of inspection substrate 310 and terminal 321 of inspection object 320 through anisotropic conductive sheet 100.

During the above-described step, inspection object 320 may be appropriately pressurized by pressing it, or may be appropriately brought into contact under heating atmosphere in view of achieving sufficient conduction of electrode 311 of inspection substrate 310 and terminal 321 of inspection object 320 through anisotropic conductive sheet 100.

As described above, in anisotropic conductive sheet 100 of the present embodiment, first conductive layer 122A is located on the inner side than the outer edge of first heat-resistant resin layer 112A in plan view of insulating layer 110. Therefore, even when terminal 321 of inspection object 320 is pushed to a position shifted from the center of gravity of first conductive layer 122A, e.g., an end portion, the load is not easily diffused to elastomer layer 111, and thus the load can be more easily transmitted to first conductive layer 122A, conductive part 121, and conductive filler 130.

In addition, even when the width of first groove 114a is reduced, adjacent first conductive layers 122A do not easily make contact with each other during the pushing. In this manner, the short circuit during the pushing can be suppressed.

Thus, even when a pushing load is applied to a position shifted from the center of gravity, the increase in resistance value and the non-uniformity of the resistance value can be suppressed while suppressing the short circuit due to the contact of the plurality of adjacent first conductive layers 122A.

### 4. Modifications

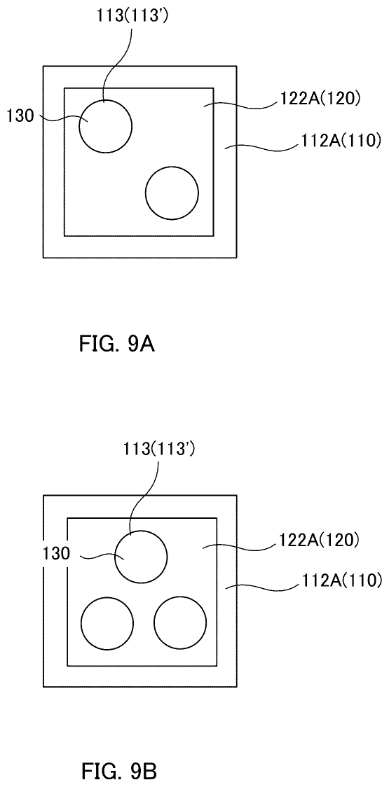

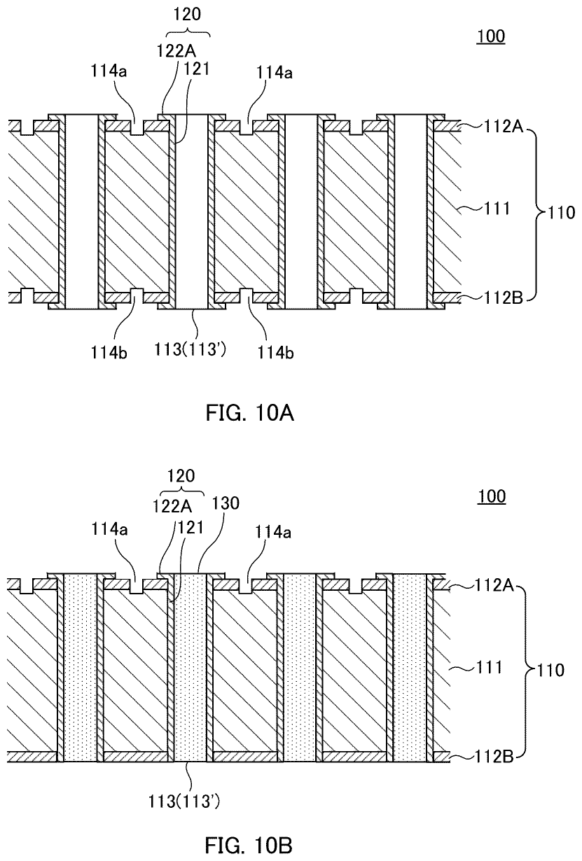

FIGS. 9A and 9B are schematic enlarged plan views of a first conductive layer of anisotropic conductive sheet 100 according to a modification. FIGS. 10A and 10B are schematic partially enlarged sectional views illustrating anisotropic conductive sheet 100 according to a modification.

In the present embodiment, one through hole 113 and one conductive part 121 are disposed for one first conductive layer 122A in the present embodiment, but this is not limitative. Two or more through holes 113 and two or more conductive parts 121 may be disposed for one first conductive layer 122A (see FIGS. 9A and 9B).

In addition, in the present embodiment, conductive filler 130 is provided in hollow 113′ corresponding to through hole 113, but a hollow not filled with conductive filler 130 may be adopted (see FIG. 10A).

In addition, in the present embodiment, second conductive layer 122B is disposed at second surface 110b, but it may not be disposed as long as the conduction in the thickness direction of insulating layer 110 can be ensured (see FIG. 10B).

In addition, in the present embodiment, in first surface 110a of insulating layer 110, region (non-groove region) 140 where first groove 114a is not formed is provided in the entirety of the outer periphery part of anisotropic conductive sheet 100 (see FIG. 3A), but a plurality of the non-groove regions may be provided so as to surround the plurality of conductive layers 120. In this manner, with the non-groove region 140 where first groove 114a is not formed, heat deformation of elastomer layer 111 can be further suppressed.

In addition, in the present embodiment, the anisotropic conductive sheet is used for electrical inspection, but this is not limitative. It may be used for electrical connection between two electronic components such as electrical connection between a glass substrate and a flexible printed board, electrical connection between a substrate and an electronic component mounted on the substrate, and the like.

### EXAMPLES

The present invention is described below with Examples. The Examples does not limit the scope of the present invention.

### Example 1

As a laminate sheet, a laminate sheet (7.5 μm/310 μm/7.5 μm) including a silicone rubber layer (elastomer layer), and two polyimide resin layers (heat-resistant resin layers) disposed on both sides of the layer was prepared. After a plurality of through holes 113 (the openings of the plurality of through holes 113 on first surface 210a side with a 85 μm circle equivalent diameter) was formed in the lamination direction (thickness direction) of this laminate sheet, a continuous gold (Au) layer was formed at the surface of the laminate sheet (the inner wall surface of through hole 113, first surface 210a and second surface 210b) by a plating method. Next, on first surface 210a of the sheet obtained, ThreeBond 3303B available from ThreeBond Co., Ltd. (containing Ag particles, silicone rubber and crosslinking agent: a crosslinked material with a volume resistivity of 3×10⁻⁵ Ω·m according to ASTM D 991) was dropped as a conductive elastomer composition, and that composition was introduced and supplied into hollow 113′ corresponding to through hole 113 through vacuum from second surface 210b side, and then crosslinked by heating it at 170° C. Next, a plurality of first grooves 114a and second grooves 114b were formed in a grid form by laser processing in first surface 210a and second surface 210b of the obtained sheet, and they were divided into the plurality of first heat-resistant resin layers 112A and second heat-resistant resin layers 112B, and the plurality of first conductive layers 122A and second conductive layers 122B. Then, the outer periphery parts of first conductive layer 122A and second conductive layer 122B were further removed by laser processing, and thus anisotropic conductive sheet 100 was obtained (see FIGS. 3A and 3B).

In the obtained anisotropic conductive sheet, on the first surface 110a side, the size of first conductive layer 122A was 160 μm×160 μm (the area ratio of first conductive layer 122A with respect to first heat-resistant resin layer 112A: 38%, the a/b=0.62), the size of first heat-resistant resin layer 112A was 260 μm×260 μm (b/c=0.87), and distance c between centers of gravity of the plurality of first conductive layers 122A was 300 μm. Likewise, the size of second conductive layer 122B, the size of second heat-resistant resin layer 112B, the area ratio of second conductive layer 122B with respect to second heat-resistant resin layer 112B, and the distance between centers of gravity of the plurality of second conductive layers 122B on the second surface 110b side were the same as those on the first surface 110a side.

### Comparative Example 1

An anisotropic conductive sheet was obtained in the same manner as in example 1 except that after the plurality of first grooves 114a and second grooves 114b were formed, the outer periphery parts of first conductive layer 122A and second conductive layer 122B were not removed.

In the obtained anisotropic conductive sheet, on the first surface side, the size of conductive layer was 160 μm×160 μm (the area ratio of the conductive layer with respect to heat-resistant resin layer: 100%, the a/b=1.0), the size of heat-resistant resin layer was 160 μm×160 μm (b/c=0.53), and the distance between centers of gravity of the plurality of conductive layers was 300 μm. Likewise, on the second surface side, the size of the conductive layer, the size of heat-resistant resin layer, the area ratio of the conductive layer with respect to the heat-resistant resin layer, and the distance between centers of gravity of the plurality of conductive layers were the same as those on the first surface side.

### Evaluations

For the obtained anisotropic conductive sheet, the average resistance value and standard deviation with different pushing loads were measured by the following method.

### Pressing Test

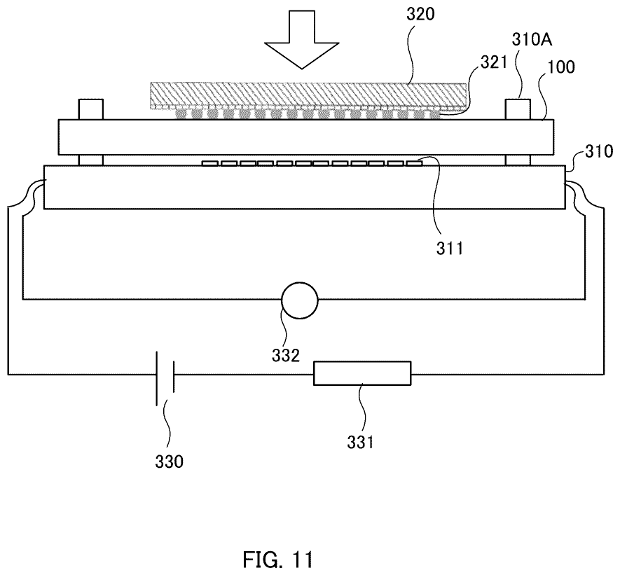

As illustrated in FIG. 11, guide pin 310A of inspection substrate 310 was inserted to the positioning hole (not illustrated in the drawing) of anisotropic conductive sheet 100, and anisotropic conductive sheet 100 was positioned and disposed at inspection substrate 310. Test chip 320 serving as an inspection object was disposed on or above anisotropic conductive sheet 100, and they were fixed by using a pressing jig.

As test chip 320, a chip was used in which a total of 264 solder ball electrodes (material: lead-free solder) with a diameter of 0.2 mm and a height of 0.17 mm were arranged at a pitch of 0.3 mm, and each pair of two of the solder ball electrodes is electrically connected to each other through a wiring in test chip 320 (see FIG. 8B).

Next, at 25° C., the electric resistance value under each load was measured by changing (increasing) stepwise the load applied to test chip 320 with a pressing jig.

### Measurement of Electric Resistance Value

The electric resistance value was measured by the following method. With DC power source 330 and constant current control device 331, DC current of 10 mA was applied at all times between the external terminals (not illustrated in the drawing) of inspection substrate 310 electrically connected to each other through anisotropic conductive sheet 100, test chip 320, electrode 311 of inspection substrate 310 (inspection electrode) and its wiring (not illustrated in the drawing), and the voltage between the external terminals of inspection substrate 310 under the pressure was measured with voltmeter 332. Electric resistance value R₁ was determined by the following Equation, where V₁ is the value (V) of the measured voltage and I₁ (=10 mA) is applied DC current.

R₁=V₁/I₁ [1]

Note that electric resistance value R₁ includes the electric resistance value between the electrodes of test chip 320 and the electric resistance value between the external terminals of inspection substrate 310 in addition to the electric resistance values of two first conductive layer 122A and second conductive layer 122B. Further, the electric resistance values R₁ were measured for first conductive layer 122A of anisotropic conductive sheet 100 in contact with 264 electrodes of the solder ball, and their average value was determined.

Table 1 shows results of the evaluation.

TABLE 1

| | Composition | | | Evaluation | |
|---|---|---|---|---|---|
| | Area | | | Average | Standard |
| | Ratio* | | | Resistance | Deviation |
| | (%) | a/b | b/c | (mΩ) | (mΩ) |
| Ex 1 | 37.8 | 0.62 | 0.87 | 143 | 12 |
| Comparison | 100 | 1.0 | 0.53 | 177 | 146 |
| Ex 1 | | | | | |

*The area ratio of the conductive layer with respect to the heat-resistant resin layer (%)

As shown in Table 1, in the anisotropic conductive sheet of Example 1 in which the area of the conductive layer is smaller than the area of the heat-resistant resin layer, both the average resistance value and the standard deviation were smaller, and the non-uniformity of the plurality of conductive interlayers is smaller in comparison with comparative example 1 in which the area of the conductive layer is the same as the area of the heat-resistant resin layer.

This application is entitled to and claims the benefit of Japanese Patent Application No. 2021-178804 filed on Nov. 1, 2021, the disclosure each of which including the specification, drawings and abstract is incorporated herein by reference in its entirety.

### INDUSTRIAL APPLICABILITY

According to the present invention, it is possible to provide an anisotropic conductive sheet that can maintain favorable conduction even when a pushing load is applied to a position shifted from a predetermined position while suppressing short circuit due to contact of a plurality of adjacent conductive layers.

### REFERENCE SIGNS LIST

100 Anisotropic conductive sheet
110 Insulating layer
110a First surface
110b Second surface
111 Elastomer layer
112A First heat-resistant resin layer
112B Second heat-resistant resin layer
113 Through hole
113′ Hollow
120 Conductive layer
121 Conductive part
122A First conductive layer
122B Second conductive layer
114a First groove
114b Second groove
130 Conductive filler
210 Laminate sheet
220 Conductive layer
300 Electrical inspection device
310 Inspection substrate
311 Electrode
320) Inspection object
321 Terminal (of inspection object)
330) DC power source
331 Constant current control device
332 Voltmeter
L Conductive elastomer composition

1. An anisotropic conductive sheet comprising:
an insulating layer including an elastomer layer, and a plurality of first heat-resistant resin layers disposed on or above one surface of the elastomer layer, the plurality of first heat-resistant resin layers being separated from one another;
a plurality of through holes disposed in the insulating layer;
a plurality of conductive parts disposed at respective inner wall surfaces of the plurality of through holes; and
a plurality of first conductive layers disposed at respective surfaces of the plurality of first heat-resistant resin layers and connected with the plurality of conductive parts,
wherein the plurality of through holes is disposed at positions corresponding to the plurality of first heat-resistant resin layers, and
wherein in plan view of the insulating layer, each first conductive layer is located on an inner side of an outer edge of each first heat-resistant resin layer.

2. The anisotropic conductive sheet according to claim 1,
wherein in plan view of the insulating layer,
each first heat-resistant resin layer has a rectangular shape, and
a ratio b/c of a length b of a short side of each first heat-resistant resin layer with respect to a distance c between centers of gravity of the plurality of first conductive layer is 0.65 or greater.

3. The anisotropic conductive sheet according to claim 1, wherein in plan view of the insulating layer, an area of each first conductive layer is 35 to 80% of an area of each first heat-resistant resin layer corresponding to each first conductive layer.

4. The anisotropic conductive sheet according to claim 1, wherein a conductive filler is further provided inside the plurality of through holes.

5. The anisotropic conductive sheet according to claim 1,
wherein the insulating layer further includes a plurality of second heat-resistant resin layers disposed on or above another surface of the elastomer layer, the plurality of second heat-resistant resin layers being separated from one another other,
wherein the anisotropic conductive sheet further includes a plurality of second conductive layers disposed on or above surfaces of the plurality of second heat-resistant resin layers and connected to the plurality of conductive parts,
wherein the plurality of through holes is disposed at positions corresponding to the plurality of second heat-resistant resin layers, and
wherein in plan view of the insulating layer, each second conductive layer is located on an inner side of an outer edge of each second heat-resistant resin layer.

6. The anisotropic conductive sheet according to claim 1,
wherein the anisotropic conductive sheet is used for electrical inspection of an inspection object, and
wherein the inspection object is disposed on or above a surface on a first conductive layer side.

7. An electrical inspection device comprising:
an inspection substrate including a plurality of electrodes; and
the anisotropic conductive sheet according to claim 1 disposed on or above a surface of the inspection substrate on which the plurality of electrodes is disposed.

8. An electrical inspection method comprising stacking an inspection substrate including a plurality of electrodes and an inspection object including a terminal through the anisotropic conductive sheet according to claim 1 to electrically connect the plurality of electrodes of the inspection substrate and the terminal of the inspection object through the anisotropic conductive sheet.
